(19) United States
(12) Patent Application Publication
(10) Pub. No.: US 2004/0088614 A1
(43) Pub. Date: May 6, 2004

(54) Management system for defective memory

(76) Inventor: Ting-Chin Wu, Taipei (TW)

Correspondence Address: Ting-Chin Wu, 235 Chung - Ho, Box 8-24, Taipei, TW

(21) Appl. No.: 10/284,523

(22) Filed: Nov. 1, 2002

(51) Int. Cl. G11C 29/00

(52) U.S. Cl. 714/718; 714/765

(57) ABSTRACT

A defect management system allows the usage of memory devices with a plurality of defective memory cells to be used for data storage. The system is especially suitable for the storage of streaming media data. The defect management system provides significant manufacturing costs benefits to products that store significant quantities of data in solid state memory, such as MP3 players or MPEG-4 video players. A non-volatile memory stores a map of defective areas within the memory devices that is generated using in Built In Self Test (BIST) procedure. The system employed are low overhead and can be realise in software code or a hardware implementation. The technique can be applied to a very wide range memory technologies include DRAM, Flash, FeRAM and MRAM.

### FIELD OF THE INVENTION

The present invention relates to memory management, and particularly to a defect management system allowing the usage of memory devices with a plurality of defective memory cells to be used for data storage. The system is especially suitable for the storage of streaming media data.

### BACKGROUND OF INVENTION

High density semiconductor memory devices consists of many millions of individual data storage cells. The aim of the manufacturing process is to build devices in which every cell is fully operational and able to reliably store data. Due to the limitations of manufacturing technique a proportion of memories that are manufactured have one or more memory cells that are defective and unable to reliably store data. This renders the memory device useless for sale as a standard product.

In most of these “partial” or “downgrade” memories the vast majority of cells work reliably. These devices are generally made available to the market at a price considerably lower than that of standard all-good parts. The level of discount is far greater than that represented by the proportion of faulty memory cells. Thus significant manufacturing cost advantages can be gained by using these parts in end applications requiring data storage. A number of techniques have been developed to use these memory devices in specialized applications.

A number of techniques have been employed to allow the use of partial memory parts in a wide range of applications. These techniques have been applied to both DRAM and Flash devices. In particular there has been significant interest in downgrade usage techniques for DRAM parts due to their widespread usage PCs. Moreover, DRAM manufacture is a highly competitive industry and during the transition to higher memory densities larger numbers of partial memories are generated as manufacturing techniques are being optimised.

DRAM and some other memory types employ internal redundancy techniques. These are extra rows and columns fabricated as part of the chip design. If, during the many stages of test that each device is subjected to, defects are found then redundant rows and columns are mapped in electronically to mask the defective areas of the chip. Non-volatile storage or fuses on the chip die allow these redundant memory areas to be mapped appropriate once the locations of any defects are known. However, even when such techniques are employed there are still significant number of memory devices that cannot be repaired. This is for two main reasons. Firstly, there are limitations on how redundant resources can be used in the die. Generally redundant rows and columns are not a global resource that can be mapped to any part of the chip. Timing and layout restrictions prevent that level of flexibility. Thus some patterns of defects cannot be repaired because they exceed the redundancy of a certain section of the device. Secondly, there is a trade off between the die area allocated to redundant resources and the percentage of parts that may be “recovered” using those resources. If too much redundancy is made available then the die size overhead of the redundancy, integrated into all devices, outweighs the benefits of the percentage of devices that may be recovered. Thus there are still significant quantities of partial memory parts manufactured that cannot be used in normal applications. However, these parts are generally sold with little information about the nature and quantity of defects. That must be established by subsequent testing.

Many partial memory devices with low levels of defects can be employed directly in certain types of low grade consumer devices and toys. For instance partial memory devices with a low defect count (given the name audio memory) are successfully employed in digital telephone answering machines. These store audio digitally in an uncompressed format. Defects within the memory only have a transient impact of speech quality and, although potentially discernable, do not significantly inhibit the functionality of the device. However, this simple technique cannot be employed in higher fidelity or devices or indeed when compression has been applied to data. The effect of compression is to intensify the impact of a single bit defect such that it can have a much more discernable impact. Moreover, there are many partial memory parts available that have many more defects than would be acceptable even in an answering machine or toy application.

A common technique used for recovering partial DRAM devices for use in PCs is termed bit plane sorting. An example of this is shown in FIG. 1. Label 101 identifies four separate memory devices. Each of these memory devices is able to read or write 4 bits simultaneously. Most common memory types have a width of at least 8 bits and often 16 or 32 bits. The data for each bit is stored within an independent block within the memory 102. In reality the data for different output bits may be physically more closely coupled together but the logical address spaces remain separate. Label 103 shows a defect in a bit plane of the first memory device. This single defect affects a large number of individual memory cells. Label 104 shows a bit plane bank that contains a defective column in the memory. Label 105 shows a bit plane bank that contains a defective row. The bit plane technique simply discards an entire plane from a memory device if it contains any defects. Label 106 shows how the data pin for a defective data plane is not connected to an external system. The set of data bits supported by the memory is labeled as 107. As can be seen only data bits connected to all good planes of data memory are actually used. Additional memory devices are used to provide the required data access width. This technique has the benefit of being very simple but has a number of distinct disadvantages. Firstly, a whole data plane must remain unused even if it only contains a few defective cells. Secondly, additional memory devices must be fitted to achieve the required data width. This requires more PCB area and power. If byte writeability is a requirement of the memory system then even more parts are required since a single part is not able to straddle two bytes with the data word. Thirdly, as the average number of defects goes up there are a large number of devices that have defects in all or at least most data planes, making them unsuitable for use with this technique. However, the actual number of defective cells in the device may still be quite small.

A more sophisticated technique is illustrated in FIG. 2. A number of defective memory devices are labeled 201. These are each connected to a special mapping ASIC 202. Internally this contains some control logic 203 and a memory array 204. This memory forms external redundancy that allows defects in the individual memory devices to be masked from data sent outside of the memory system on the external bus 206. A map of all the defects on the individual memory devices is stored in a non-volatile memory device 205. Whenever the control logic encounters an access to a defective address it switches in the appropriate section of the redundant memory array. In this way only the defective cells need redundant storage and a high level of utilisation of the partial memory devices can be achieved. However, this technique also has a number of disadvantages. Firstly the ASIC 202 needs to be in the data path between the memory and the rest of the system. For high speed systems this can have a significant timing performance impact. Secondly, the manufacturing process is complex. Each of the partial memory devices must be tested and an individual map of its defects stored for later programming into the defect map memory 205. Thus the individual parts have to be tracked through the manufacturing process. Testing the parts and obtaining a full and accurate defect map down to cell granularity is also extremely challenging, especially when coupled with the requirement to keep the testing process low cost in order to avoid significantly detracting from the original cost benefits of employing partial memory devices.

### SUMMARY OF INVENTION

This section summarizes the invention. The section starts with a discussion of the types of application for the technique. This is followed by a section describing the overall physical and system architecture. Next the basic techniques employed are described and the methods used to select memory devices suitable for use in this manner. Finally there is a description of how to improve defective part utilisation by statistically analyzing defect distributions within the memory arrays.

Preferably, the defect management system is designed to work with streaming media formats for audio or video storage. These are data files that generally contain compressed forms of the audio and/or video data. This type of data has a number of important characteristics that make them suitable for use in this type of environment.

These data files are designed for transmissions across lossy network mediums. Thus some data packets may be lost that will cause a temporary interruption to the playback. However, the data formats contain suitable internal synchronization to allow the playback to continue normally after the interruption. Thus no packet contains crucial information that would render the remainder of the playback data useless. Examples of such formats are MPEG-1 Layer 3 audio (MP3) and MPEG-2 video.

The various objects and advantages of the present invention will be more readily understood from the following detailed description when read in conjunction with the appended drawing.

### BRIEF DESCRIPTION OF THE DRAWINGS

FIG. 1 shows a prior art bit plane system employed for making use of memory devices with a number of defective cell locations.

FIG. 2 shows a more sophisticated prior art system for reclaiming defective memory parts. This uses an external ASIC with internal memory resources to correct the defects in a number of individual memory devices.

FIG. 3 shows an overall of the framed format of media data that is well suited for storage within devices using the defect management techniques described here.

FIG. 4 shows the physical memory architecture of a product employed the defect management system described here.

FIG. 5 shows the overall system architecture of the defect management system, showing both the physical memory blocks and the control modules that are implemented in either hardware or software that perform the defect management.

FIG. 6 shows an example memory array with a number of defects. A square memory defect block is shown in order to illustrate the impact of the defects in terms of the number of blocks that are marked as being unusable.

FIG. 7 shows the same memory array as FIG. 6 including the same defects. The example content of a non-volatile memory storing the defect pattern is shown.

FIG. 8 shows the same memory array as FIG. 6 with the same defects. A horizontally elongated mapping block is shown in order to illustrate the impact of mapping block shape on the total number of cells that must be marked as bad.

FIG. 9 shows the same memory array as FIG. 6 with the same defects. A vertically elongated mapping block is shown in order to illustrate the impact of mapping block shape on the total number of cells that must be marked as bad.

FIG. 10 contains a process flowchart that is employed in order to screen memory devices that are to be used in products employing the defect management system described here.

FIG. 11 shows an example of storage of directory data in partially defective memory system. Data redundancy and a majority voting system for reading data are employed in order to preserved data integrity.

FIG. 12 shows the internal structure of several mapping blocks. The checksum present in each mapping block is illustrated.

FIG. 13 illustrates the defect map caching mechanism.

FIG. 14 shows the impact of internal chip address topology on the impact of defects on the number of mapping blocks that must be marked as unusable. A simple mechanism to counteract the negative impact of address topology is shown.

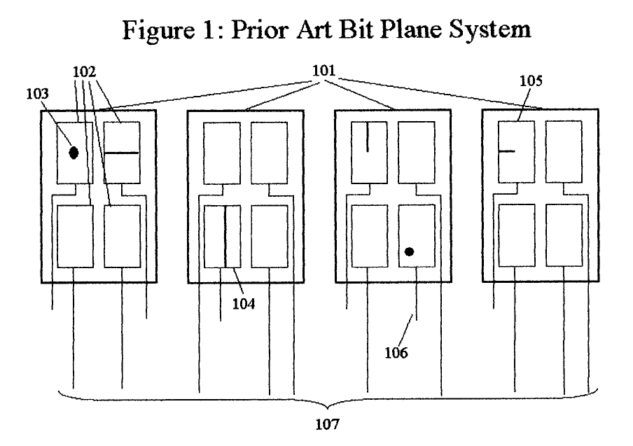

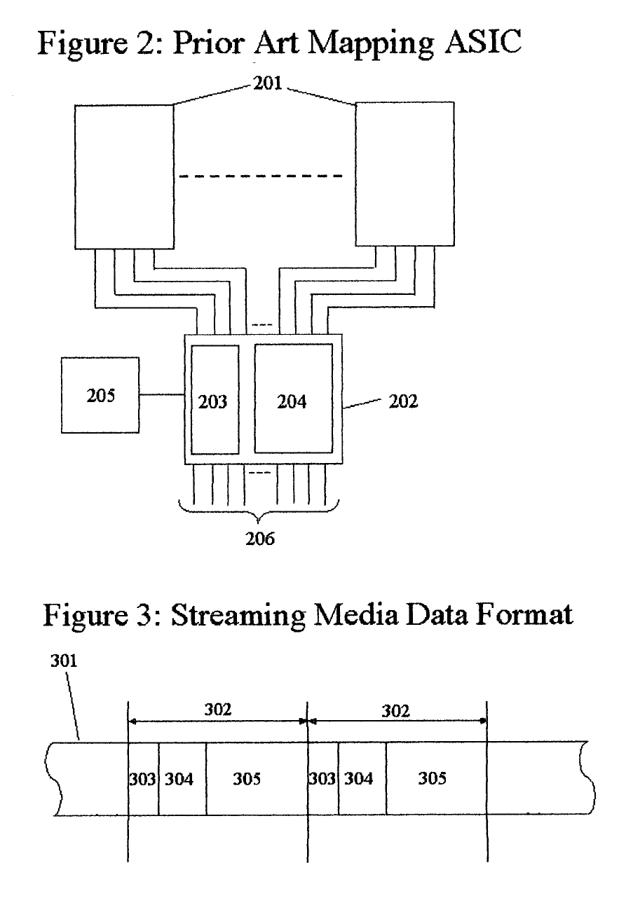

### DESCRIPTION OF THE PREFERRED EMBODIMENTS

An embodiment of the present invention is shown in FIG. 3. The section of the stream is labeled as 301. The stream consists of individual frames 302. Each of these frames may be of the same size or variable size depending on the format employed.

Each frame begins with a frame synchronization 303. This allows the start of frames to be determined even in the event of packet loss or corruption in data transmission. A frame header 304 gives information about the contents of the frame. Finally the data payload of the frame 305, contains the media content.

Files of this nature are especially suitable for storage using the type of defect management system described here. Although initial testing is performed to find the vast majority of defects in the memories, a small number of defects may be found during life. These defects must not have a catastrophic impact on the performance of the device. When used with streaming media files the impact of a defect will be a very short and temporary effect on the quality of the playback. In many cases this will be barely discernable to the user.

The defect management technique is especially suitable for devices in which data is effectively cached for subsequent playback on a device. The data stored will not be transferred out of the device onto another storage medium. An example of such a product is a portable MP3 audio or MPEG-4 video player. Media files are downloaded from a PC for storage, and subsequent playback on the device.

Note that the defect management technique is best suited to storage of streaming media formats but is not exclusively so. If the test coverage during the Built-In Self Test is sufficiently good then the mapping blocks marked as being good may be used for reliable storage of any type of data.

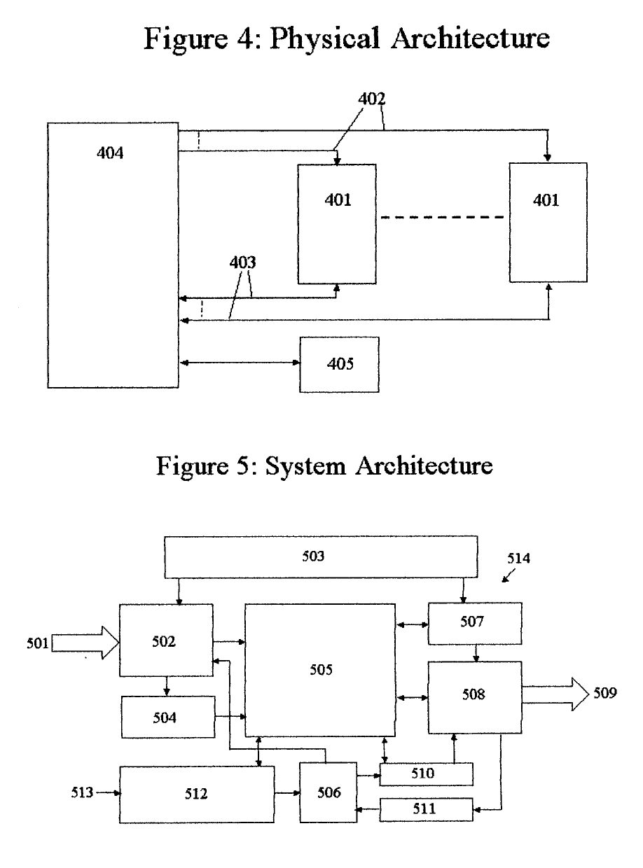

The physical architecture of a system using the defect management system is shown in FIG. 4. The system has a number of memory devices 401. The system is not limited in the number of memory devices used although a minimum of one is required. Any number of those memory devices may be partial in nature. That is they may be parts that contain a number of defective cells. There is a no intrinsic limit on the number of defects in any given part although the number of defects may have to be limited in order to ensure a certain memory capacity for the overall product.

The memory devices are controlled by the address and control signals 402. Depending on the memory architecture there may be independent signals routed to each memory device or they may share common control and address signals, apart from an individual device select.

Data is written to and from the memories using the data buses 403. Again, depending on the memory architecture these may be separate signals for each memory or may be common for all. Typical memory architecture use a number of memory devices in parallel in order to provide a greater data access width than that provided by any memory individually. This provides much greater access bandwidth to the memory system. However, in systems where memory bandwidth is less important a common data bus structure may be employed in order to reduce the physical pin count of the memory controller.

The memory controller is labeled 404. This is typically a microprocessor and is responsible for controlling the accesses to the memory system. The memory controller is connected to the defect map memory 405. This is a non-volatile memory of much smaller capacity than the main memory array and is used for storing a map of the defective areas within the memory array. The memory controller accesses the relevant areas of the defect map when it needs to access the memory array in order to avoid defective cells. The memory controller is also responsible for updating the defect map during usage of a product if new defects are detected.

The overall system architecture is shown in FIG. 5. The system architecture is labeled 514. A steam of media data for storage in the system is received as labeled 501. The actual low level format of this data has no impact on the way the defect management system operates so it may be viewed as a black box subsystem by the rest of the product implementation. The data write controller 502 determines the address in main memory that the input data will be written to for storage. For instance, the input data 501 might come from a PC interface that is writing MP3 audio data for storage in the product.

An overall controller 503 determines the mode of the defect management system and whether it is storing or retrieving data at any given point. This block will also have an interface to the rest of the product so that the overall application can dictate the behavior of the defect management system.

A directory write controller 504 is tightly coupled to the write controller. The directory controller stores information such as the start and end address in memory of a particular media file or segment of file This allows the data to be subsequently retrieved. The directory information is written to a predefined area of the main memory.

The memory array is shown in the center of the diagram labeled with 505. This may be composed of a plurality of individual partial memory devices. A standard address decoding scheme is employed to select the correct individual device depending upon the presented address. The memory controller receives data and addresses from the data write and directory write controllers. Items may be accessed in the memory by data read and directory read controllers. Since the memory devices employed are partial any given cell in the memory array may be defective and thus unable to reliably store a data bit.

A map of the defects in the memory array is held in the defect map memory 506. This is a non-volatile memory with a capacity that is typically only a small proportion of that of the main memory array. It stores a map of the locations of the defective blocks within the main memory array itself.

The directory read controller 507 is able to retrieve the start and end information stored in the memory by the directory write controller. Thus the address of the start and end of data for a particular media file can be determined.

The data read controller 508 reads the data back from the memory and sends it to the output channel 509. This is connected into the rest of the system as required to provide the required functionality. For instance this might be connected to an MP3 decoder subsystem that plays back data previously stored on a device from a PC interface.

The defect cache controller is labeled 510. It is responsible for storing a cached copy of the defect map associated with a particular media file as the file is being written. This cached defect map may itself be stored in the main memory. The cached version represents the state of the defects at the time the media file was written.

A new defect controller module 511 is illustrated. This is responsible for adding new defects to the defect memory that have been detected during the usage of the product.

Finally there is a Built-In Self Test (BIST) unit 512. This is responsible for running a series of test patterns on the memory array and capturing the set of defects found into the defect map memory 506. This sequence of tests is generally only performed the first time the product is powered up or when it is powered up in a special test jig used during the manufacturing process. The signal 513 indicates when the BIST tests should be performed.

The cells within the memory devices are subdivided into a number of mapping blocks. Each mapping block consists of a number of cells in the memory device. The mapping block represents the smallest granularity area that may be marked as good or bad by the defect management system. A mapping block is marked as bad if it contains any defective memory cells. For a mapping block to be marked as good, all the cells within that block must have reliably stored data for all the memory tests performed upon those cells. Note however that later usage of that block may show that under certain circumstances it is not able to store data reliably. In that case the block must transition from good to bad state Note that there is no case in which a block transitions from a bad to a good state.

The number of cells within the mapping block determines the capacity relationship between the main memory array and the size of the defect map memory required. Only a single bit is required to represent a mapping block within the defect map memory. This simply shows if the block is good or bad. For instance, if each mapping block contains 1024 cells and the memory array is 64 MB in size then the defect map memory needs to be 64 KB. The defect management system allows the size of the mapping block to be configurable to match the requirements of the application. Larger mapping blocks minimize the requirement for defect map memory but have the disadvantage of greater wastage of good cells in the memory array. Even if a mapping block only contains a few bad cells then the entire mapping block needs to be marked as defective and no cells are used within it.

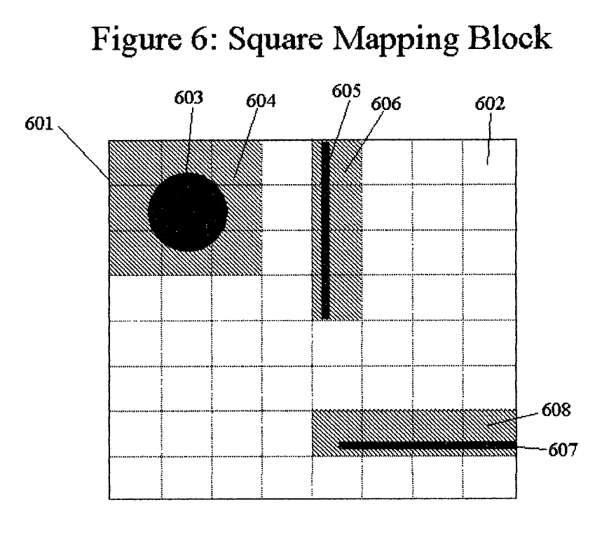

FIG. 6 shows a memory array containing a number of defective cells, 601. The memory is composed of individual mapping blocks 602. The memory array contains a large defect 603 that affects a large number of neighboring cells. Any mapping block that contains any defective cells must be marked as bad. These are shaded on the diagram. The label 604 indicates the area of bad mapping blocks caused by the defect 603.

The memory array also contains a column defect 605. Row and column defects are very common in memories due to the underlying physical architecture that as tracks connected the individual memory cells both horizontally and vertically through the memory array (the word lines and the bit lines). If these connections are shorted or damaged in some way then a defective row or column is the result. The mapping blocks that are marked bad due to the column defect are labeled 606.

The memory array also contains a row defect 607. The set of mapping blocks marked as defective due to the defect is labeled 608.

In general the number of rows of cells and columns of cells within a mapping block will be a power of 2. This allows the correct address of the bad flag in the defect map memory to be derived from the main memory address in a straightforward manner. Simple bit shift and addition operations can be used to compute the address. This is especially important if a relatively low performance microcontroller is used to implement the defect management system in software.

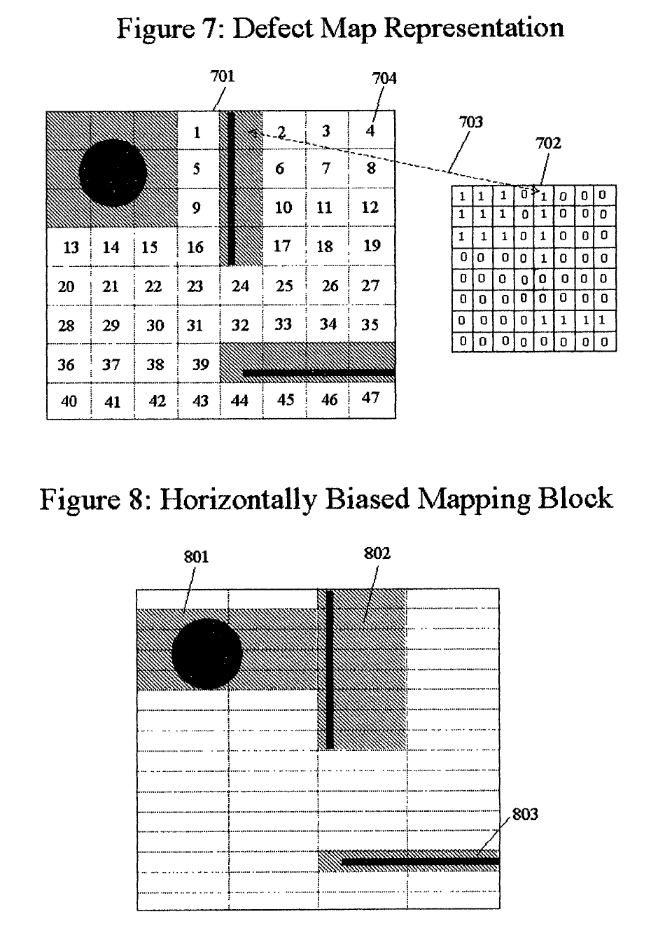

FIG. 7 shows the relationship between the memory array defects and the corresponding defect map memory. The memory array with defects is labeled 701. The defect map memory is labeled 702. A single bit in this memory corresponds to each mapping block in the memory array. In this example a defect map content is 1 if the mapping block is bad and 0 if the block is good. However, the inverse convention could be used. The label 703 shows the correspondence between a mapping block in the main memory and bit in the defect map memory.

When data is being written to or read from the memory array the defect map is examined. Data is accessed from contiguous locations within a particular mapping block. When the end of a mapping block is reached the address is incremented to point to the start of the next good mapping block. In this way defective mapping blocks are skipped over during the writing or reading of data in the memory. The numbers within each of the good mapping blocks illustrates this, as labeled 704. These numbers represent the order in which the 47 good mapping blocks in the memory array might be accessed.

The shape of the mapping blocks has a direct influence on the number of mapping blocks that need to be marked as bad, depending upon the physical structure of the defects themselves. FIG. 8 shows the same memory array and defect pattern as shown in FIG. 6. However in this case the mapping blocks are horizontally biased in shape. That is they contain longer row segments than column segments from the memory array. Note that the total number of cells within each mapping block is identical to that in FIG. 6 and thus the size of the defect map memory required is the same. The area 801 shows the mapping blocks marked as defective for the circular defect. A total of 8 blocks are marked bad compared to 9 in FIG. 6. Thus there is no significant difference. The area 802 shows the mapping blocks marked bad due to the column defect. A total of 8 blocks are marked as bad compared to 4 in FIG. 6. Thus horizontally biased mapping blocks are much less efficient at mapping columns than square blocks. The area 803 shows the mapping blocks marked bad due to the row defect. Only 2 mapping blocks are marked as bad, compared to 4 in FIG. 6. Thus horizontally biased mapping blocks are much more efficient at handling row defects. In the extreme case a mapping block can be composed of all columns from the memory array but only be a single row in height.

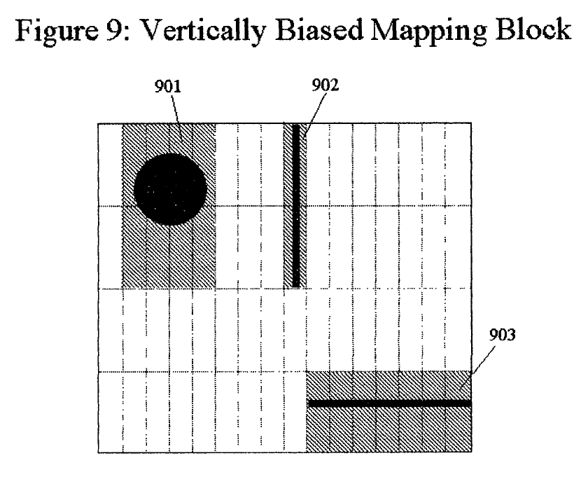

FIG. 9 shows the same memory array and defect pattern as shown in FIG. 6. However in this case the mapping blocks are vertically biased in shape. That is they contain longer column segments than row segments from the memory array. Note that the total number of cells within each mapping block is identical to that in FIG. 6 and thus the size of the defect map memory required is the same. The area 901 shows the mapping blocks marked as defective for the circular defect. A total of 8 blocks are marked bad compared to 9 in FIG. 6. Thus there is no significant difference. The area 902 shows the mapping blocks marked bad due to the column defect. Only 2 blocks are marked as bad compared to 4 in FIG. 6. Thus vertically biased mapping blocks are much more efficient at mapping columns than square mapping blocks are. The area 903 shows the mapping blocks marked bad due to the row defect. A total of 8 mapping blocks are marked as bad compared to 4 in FIG. 6. Thus vertically biased mapping blocks are much less efficient at handling row defects. In the extreme case the mapping block could include all rows from the memory array and but only be one column wide. However, this tends to be a power and performance inefficient choice, as the access time to obtain a new row from memory tends to be much greater than to obtain data from different columns in the same row. Each row access also consumes significantly more power than an access to a different column in the same row.

Thus in general the size and shape of the mapping blocks are configured to match the relative sizes of the main memory and defect map memory available and the general distribution of defects found in the memory devices. If there is a strong bias to row defects then horizontally biased blocks are used. If there is a strong bias to column defects then vertically biased blocks are employed.

The purpose of the Built In Self Test (BIST) is to test the partial memory devices in order to generate a defect map. If sufficient test coverage is obtained then the vast majority of defects within the devices will be found and logged within the defect map memory. The defective areas of the partial memories will then be avoided for data storage. Thus only a relatively small number of additional defects will be discovered during the lifetime of the product.

The BIST uses the same microcontroller or other hardware mechanisms to exercise the memory as is used during the normal operation of the defect management system. Thus there is effectively no additional product cost incurred because of the requirement to perform BIST. The functionality is required anyway. This further lowers the cost using partial memory devices in comparison to some prior art techniques. Since the testing is done on the final product once memory devices have been integrated into the product there are no issues with tracking the defect maps associated with particular physical devices through a manufacturing process. Moreover, the spurious defects induced by poor conductivity in the device sockets of a tester are avoided. The partial memory devices are testing in exactly the same electrical environment as they are used in within the final product.

The BIST is normally occurs the very first time that the product is powered up during the manufacturing process. Alternatively, the BIST process may be initiated by a set of external input signals to the system that cannot occur during the normal usage of the product. The BIST testing can take an extended period time since the test process does not require the resources of an expensive memory tester.

During the BIST process the environmental conditions, such as voltage and temperature, may be optionally varied from normal. This allows more extensive test coverage during BIST and thus a reduction in the number of additional defects found during the product's lifetime.

At the start of the BIST process the defect map memory is cleared in order to mark all areas of the partial memories as being good. As defects are detected during the testing, mapping blocks are marked as bad. In effect the BIST corresponds to a formatting operation to determine bad areas, much like the formatting of magnetic data storage media.

The BIST may consist of any set of test patterns. However, it will generally contain a number of marching test patterns that address the memory in both increasing and decreasing addresses along with varying patterns of data. These tests are designed to uncover stuck-at faults in the memory (i.e. a cell can only store a 1 or a 0 reliably) and coupling faults between adjacent cells in the array. For DRAMs, which require a periodic refresh, the maximum refresh time is exceeded during certain tests in order to detect weak memory cells that have high leakage and are thus not able to reliably hold their data.

When all tests have completed a check is made to ensure that the remaining good capacity of the memories is greater than a predefined minimum. If not then the device is deemed to have failed. The BIST may also contain iterative tests that keep testing the memory until no new defects are detected. This allows greater testing effort to be exerted on devices that have high numbers of defects or are unstable in some way.

Before partial memory devices can be used in a product they must be subjected to a screening process. This ensures that they have enough working cells to be useful in the product and that they do not violate any parametric maximums. For instance, they must not exceed a maximum standby current. Partial memory devices often have inferior parametric performance to all good devices due to internal shorts associated with the defective cells.

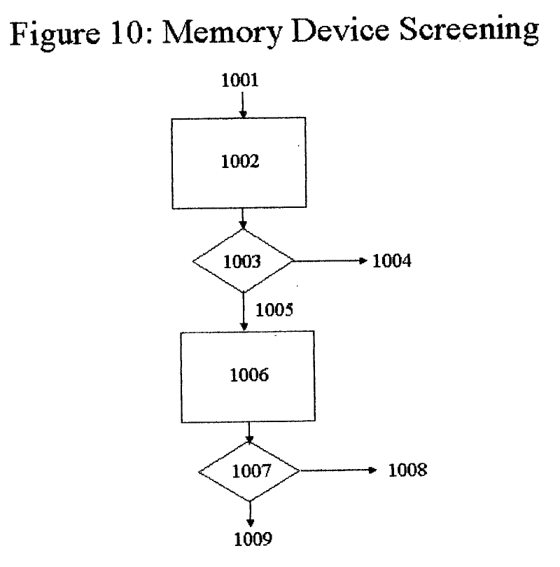

FIG. 10 shows a flowchart for the screening process, Unsorted partial memory devices enter the process as labeled 1001. They enter a screening process 1002. During this process they are subjected to a number of tests. These include functional memory tests and parametric tests. These tests are not designed to be exhaustive but simply provide an indication of the number of defective cells on a particular device. A number of different memory test environments may be used for the screening process. One possibility is to use commercial memory testers with appropriate package handlers. However, these testers are optimised for testing all good memory devices and a generally not capable of counting the number of cell defects on a memory device and using that as a pass/fail criterion. For DRAM parts, another option is to use a PC based tester. Memory devices are loaded into a carrier of zero-insertion force sockets and plugged in as a second memory module in a PC. A known good memory module, from which the operating system and applications are executed, occupies the first module slot. A memory test program performs checks on the module under test, counts the defects and indicates which parts are within a maximum defective cells count. A third option is to screen the parts in the environment of the final product itself. A variant of the product with zero insertion force sockets for the memory parts is used. The standard BIST can then be run in order to screen the parts. Feedback is generated from the product showing which parts have passed and which have failed.

Environmental parameters may be varied during the screening process in order to improve the effectiveness of the testing. For instance the tests may be performed on the parts while they are subjected to an elevated temperature. The access time requirements on the parts may also be made more stringent than required in the final application. In general guard bands are applied to all test parameters to reduce the probability of parts falsely passing the screening criteria.

The label 1003 shows the screening decision point. The screening decision is based on the parts have less than a maximum number of defective cells (or defective mapping blocks if the BIST test mechanism is used) and passing the parametric screening requirements. The flow of failed parts is labeled 1004. These parts may be discarded or used for some lower grade usage. The flow of passing parts is labeled as 1005. These parts are then used for assembly on products using the defect management system.

The process 1006 represents the BIST performed by the product. This occurs once the product has been fully assembled with the partial memory devices and is powered up for the first time. The defect map is written to the non-volatile defect map memory so is available whenever the device is subsequently powered up.

After the BIST is completed a pass check is performed on the products, as labeled 1007. This test is based on a certain minimum memory capacity being available in the product after finding the defective block during the BIST process. The partial parts used have been screened and there will be a significant guard band applied during that testing process. Thus the number of failures at this stage should be extremely small. The flow of failed products is labeled as 1008. These products must either be scrapped or reworked by replacing the memory parts with the greatest numbers of defects. Finally, good product suitable for shipping is shown labeled as 1009.

In addition to the storage of media data, directory information also needs to be stored in the device. This must be held in the same partial memory devices as the media data. In terms of total storage requirement the directory data is generally extremely small in comparison to the size of the media data itself. The directory data holds information such as the start and end positions of particular media files or other associated attributes. The directory data must be stored with very high reliability, as corruption would make whole media files inaccessible.

Although the partial memory will have been tested using the BIST there is still the possibility that additional defects may be discovered during lifetime of the product. In general the probability of such an error occurring is too high to allow directory information to be stored directly in the main memory array. An additional level of redundancy must be provided to ensure that directory information can be always be reliably recovered. A redundancy and majority voting scheme is employed to achieve this.

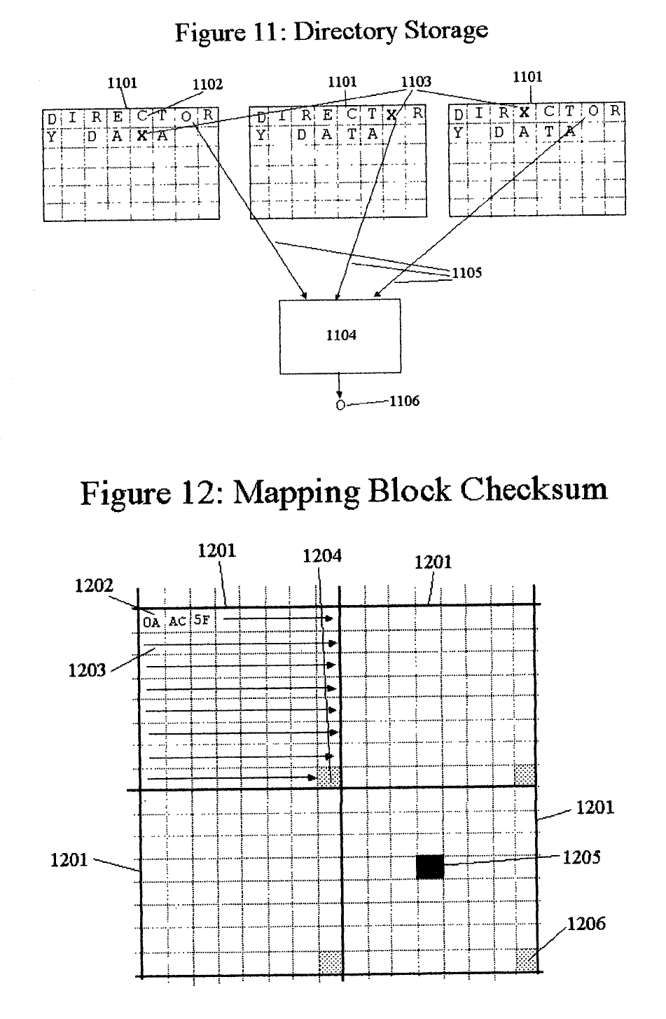

FIG. 11 illustrates this scheme. A segment of directory information is stored three times in memory devices 1101. In general the copies will be stored in physically different memory devices to insulate them from common mode failures affecting the whole of a memory device. However, in some circumstances the different copies may be stored in different areas of the same memory device.

An individual byte from the directory information is labeled as 1102. An X marks bytes that have been corrupted from their correct values, as labeled 1 103. In general the proportion of bytes that will become corrupted will be very small.

Whenever data is read from the directory each byte is read from each copy. The majority voting controller is labeled 1104. It is responsible for reading the different copies of data from the directory and determining the correct value for a byte. A simple majority vote is used. Thus if two copies of the data item are the same then it is that value that is returned. Thus a single copy can become corrupted without affecting the integrity of the stored data. The number of copies of the directory can be increased to improve the immunity from corruption.

An example set of reads is shown labeled as 1105. Each of these reads the same data byte from different copies of the directory data. The correct data byte is the character “O”. However, the second copy has been corrupted. The majority voting controller is able to still retrieve the data from the two remaining correct copies and return the correct value “O”, as labeled 1106.

It will be appreciated by those skilled in the art that other mechanisms can be employed to provide reliable storage of directory data. For instance, Error Correcting Coding (ECC) schemes may be applied to the directory date. These store additional error recovery bits that allow the original directory data to be reproduced even in the presence of a number of bit errors in the original data. However, these techniques have the disadvantage that they are mathematically more complex and take considerably more processor time if implemented in software on a relatively simple microcontroller.

The tests performed during BIST are designed to catch the vast majority of defects in the partial memory devices. However, these tests cannot be guaranteed to be exhaustive as no mechanism may be provided to guard band the testing in terms of timing or environmental conditions. Thus it is possible that additional defects will be detected during the lifetime of the product. This will have a small impact on the playback quality of the media files but should not be discernable in most circumstances.

Whenever a defect occurs during the product lifetime a mechanism is required both to detect that defect and to mark the mapping block in which the defective cell resides as bad. Thus that mapping block will not be used in the future for data storage. This mechanism allows the product to gradually learn about new defects during its life.

A checksum is employed to allow the detection of new defects encountered during life. This is illustrated in FIG. 12. The labels 1201 show the individual mapping blocks within the memory array. These are shown as 8 by 8 blocks of cells. These blocks may be replicated across multiple data planes of the device, perhaps 8 bits. Thus two digit hex values are associated with each cell in the figure as shown labeled by 1202. The number of bits associated with each cell is dependent upon the memory architecture employed. Moreover, each mapping block is likely to be of a larger size in real systems. Data is written contiguously within a mapping block as shown by the arrows labeled with 1203.

Within each mapping block a checksum is also stored. This is shown as the final value in the block and is labeled 1204. The checksum represents the total value of all the other stored values in the mapping block. If data becomes corrupted within the mapping block then that will be detected by use of the checksum. As data is read a running checksum is calculated. It is then compared against the stored checksum value. If they differ then corruption has occurred within the mapping block due to defective cells. The mapping block may then be marked as being defective in the defect map memory. It is possible that if a sequence of bytes becomes corrupted then the same checksum value might be produced and thus the error go undetected However, the probability of this is very small Note that the defect management system needs no knowledge of the meaning of the data bytes in order to employ the mechanism.

Use of a checksum does not allow a determination to be made about which particular cell or group of cells were defective. However, this is not a requirement since all the data items involved in the checksum are within the same mapping block and so the whole mapping block can be marked as bad.

The label 1205 shows a cell that is defective and thus not able to reliably store data When the data from the mapping, block is read back this will be detected using the associated checksum 1206. The discrepancy between the calculated and stored checksum will cause the mapping block to be marked as bad so that it is not used in the future for storing data.

It will be appreciated by those skilled in the art that a mechanism other than a simple checksum can be used. For instance a Cyclic Redundancy Check (CRC) could be used to more reliably detect corruption of data within a mapping block. However a disadvantage that it is more time consuming to calculate. This is an important consideration when the defect management system is being implemented in software on a low cost microcontroller.

Certain restrictions are employed to prevent too many mapping blocks being marked as defective during a single read of a media file. This is because each time a new mapping block is marked as defective the capacity of the product is reduced. The checksum mechanism is unable to differentiate between checksum failures caused by memory defects or some other cause of data corruption within the system. If all the memory becomes corrupted due to some external cause (perhaps due to a power failure) then playback of media files must not mark all mapping blocks as bad as that would render the product useless. Thus a maximum number of new bad blocks are set as a fixed parameter for the product. Once that limit has been exceeded for the read of a particular media file any additional checksum failures encountered are ignored.

An alternative implementation of this approach uses an Error Correcting Code (ECC) in each mapping block rather than a simple checksum. This requires a greater proportion of the total storage but has the advantage that many types of errors can be corrected. Different lengths of ECC provide different capabilities in terms of the total number of errors that may be corrected. In this approach the errors are corrected, as part of the read process, so there is no degradation in read quality. However the mapping block is still marked as being defective since the next time data is written to it the defects may exceed the total amount correctable by the ECC. The device handles this process invisibly with no impact on quality. Use of this process allows data requiring high levels of integrity to be stored using partial memory devices.

When a new defect is detected during usage the offending mapping block is marked as bad in the defect map memory. However, if the defect map memory is used for determining which mapping blocks to skip for reading of data this leads to a problem. If the same file is subsequently read again after the defect has been detected the first time then the whole mapping block will be skipped. Thus a large chunk of data that was originally present in the file will be missed causing a very significant degradation in the quality of media playback. In general this will be far worse than that cause by the original defect itself.

Thus the state of the defect map at the time when the media file was first written must be cached. It is this cached defect map information that is used for determining which mapping blocks are bad during the reading of the file When new data is written to the memory then the cache is updated from the defect map memory. The defect map cache may be stored in the memory array itself. Since reliable data storage is required for this cached information the same majority voting scheme employed for the directory information can be used.

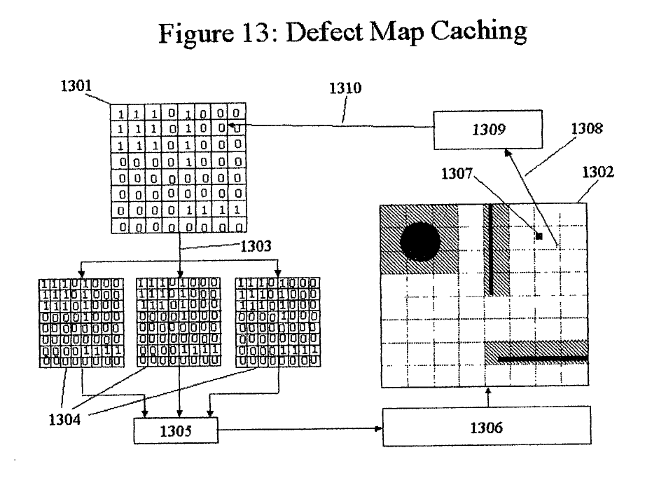

This process is shown in FIG. 13. The label 1301 shows the contents of the defect map memory as determined by the defect pattern shown in the main memory array, labeled with 1302. When data is written to the main memory array the contents of the defect map cache is copied to multiple partial memory devices as illustrated by 1303. The sections of the partial memory devices that hold the cached data are labeled 1304. In general only those parts of the defect map that are relevant to the data stream being written need be stored. This allows different media files to be independently read and written on the system and the caching updated appropriately.

The majority voting controller is labeled 1305. This feeds its results to the read controller labeled 1306. The read controller is responsible for generating the addresses to the main memory during the reading process and skipping over defective mapping blocks.

A new defect in the memory is shown labeled as 1307. As the data is read back this will be detected due to the discrepancy of the stored checksum and that calculated from the data. The label 1308 highlights the read of the checksum. The checksum is used by the defect detection block 1309. When the new defect is detected the appropriate bit in the defect map memory is changed to reflect the mapping block as being bad. This is shown by the write labeled by 1310. The appropriate bit is changed from a 0 to a 1.

The cached copies of the defect map will still hold the previous value in the defect map. Thus if the same media file is read again then the mapping block containing the defect will still be included in the read and the same defect will be detected again. It is only when new data is written to the memory array that the defect map cache is updated to include the newly determined defective mapping blocks.

The distribution of defects in the memory array is influenced by a number of factors associated with the physical layout of the memory device internals. In some cases a defect only affects a single memory cell. However, in many cases a single physical defect affects a whole group of physically adjacent memory cells. This could be a whole row or column segment if a word or bit line, respectively, is affected.

Groups of defective bits in the physical address space does not always lead to groups of defective bits in the logical address space observed externally to the device. This is because many memory devices have an internal topology mapping that is related to the physical tiles of cells within the device.

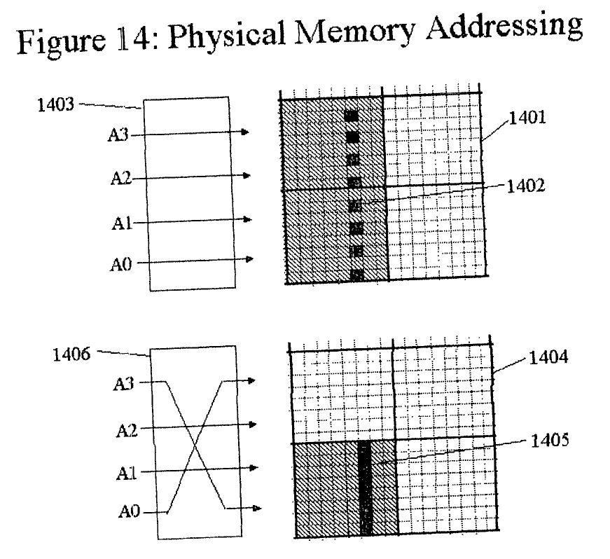

This is illustrated in FIG. 14. A single column defect 1402, becomes distributed in the logical address space of the memory device. The view of the defects in the memory device is shown labeled as 1401. The column only affects every other row in the device. Thus data can be reliably stored in the intervening rows. Unfortunately two whole mapping blocks must be marked as being bad. This view of the defects is obtained using straight-through row addressing as illustrated by the block 1403.

It is possible to reduce the affect area of the defects by applying a one-tone transformation of the row address space as illustrated by the block 1406. This simple swaps the A3 and A0 row address bits and is thus relatively easy to perform in software even on a simple microcontroller. The address space to the left hand side of this transformation is termed the physical address space and that to the right the logical address space. In effect the transformation performs the inverse mapping of the internal chip layout that leads to the distribution of a single defect as illustrated by 1402. All addressing of the device is performed in the physical address space that is converted to the logical address space prior to accessing the memory device. The revised view of the defects in the logical address space is shown in the memory array 1404. The column defect, 1405, now only affects contiguous rows. Thus only a single mapping block need be marked as being bad, improving the amount of usable space available on the part.

The physical to logical mapping function can be derived by simply inverting the internal topology mapping performed by the memory device. Unfortunately this mapping is internal to the device and manufacturers do not always freely publish the required information. However, the topology can actually be determined statistically by looking at population of partial memory parts. A heuristic search algorithm can swap various address bits to determine the impact on the number of defective mapping blocks within the devices. A good approximation to the internal topology mapping of the device is found when the total number of bad mapping blocks across the population of partial memory devices is minimized.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A defect management system comprising:
at least one memory device having a number of defective storage cells; and
a non-volatile memory having a plurality of memory blocks for storing locations of defects within the memory blocks;
wherein the defect management system tests the defective memory devices and configures the non-volatile memory to indicate locations of defective areas within each memory device and detects and adds new defects to a defect map in the non-volatile memory during use of the system

2. The defect management system according to claim 1I wherein the data being stored is frame-delimited such that defective bits appearing during the product lifetime will only result in a short interruption to full quality media playback.

3. The defect, management system according to claim 1, wherein said defect management system is implemented in firmware on a microprocessor.

4. The defect management system according to claim 3, wherein one of the firmware functions is a directory write controller for storing start and end addresse of data files stored in said defective memory devices.

5. The defect management system according to claim 4, wherein one of the firmware functions is a directory read controller for retrieving the start and end addresses of data files stored by the directory write controller.

6. The defect management system according to claim 5, wherein the firmware functions is a defect cache controller that maintains a copy of the defect map associated with a particular data segment.

7. The defect management system according to claim 6 wherein the defect cache controller stores a copy of the defect map in the at least one memory device.

8. The defect management system according to claim 1 wherein a new defect controller is responsible for detecting and adding new defects detected during the use of the system.

9. The defect management system according to claim 1, further comprising a Built-In Self Test mechanism for initially setting the state of the defect map memory.

10. The defect management system according to claim 9 wherein the Built-In Self Test mechanism is implemented in firmware on an embedded microprocessor.

11. The defect management system according to claim 10, wherein the Built-In Self Test mechanism is initiated by a set of external inputs to the embedded microprocessor that cannot be generated during normal operation in the lifetime of the product in which the defect management system is incorporated.

12. The defect management system according to claim 1, wherein the at least one memory device is formed by a memory array, and defect blocks of the at least one memory device includes an array of addressable memory locations in the memory array.

13. The defect management system according to claim 12 wherein dimensions of the defect block are powers of 2 so as to simplify the translation of memory addresses to mapping block addresses

14. The defect management system according to claim 12 wherein the dimensions of the defect block are adjusted depending upon a shape distribution of the defects detected in the memory devices.

15. The defect management system according to claim 3, wherein the defective memory devices are tested outputs of a screening process for checking minimum usable storage capacity within the devices.

16. The defect management system according to claim 15, wherein the screening process is performed by the embedded microprocessor.

17. The defect management system according to claim 1, wherein a directory information is held in a redundant fashion across the at least one memory device in order to provide reliable storage for such data.

18. The defect management system according to claim 17 wherein the directory information is read via a voting controller that is able to retrieve valid information if a minority of directory information bytes is corrupted.

19. The defect management system according to claim 1, wherein a checksum is associated with stored data values within a selected defect block.

20. The defect management system according to claim 19, wherein if the checksum (1204) is not matched to the sum of the stored data values then the defect block is marked as being defective in the defect map memory.

21. The defect management system according to claim 19, wherein a cache of a segment of the defect block is stored in a redundant manner in the main memory in order to cause the read controller to avoid reading data from defective memory blocks.

22. The defect management system according to claim 21 wherein detection of a new defect causes immediate update of the defect memory but the update of the cached copies is delayed until new data is written to the main memory array.

23. The defect management system according to claim 1, wherein a transformation of at least one row and column addresses of the memory device is applied to reduce the average number of defective mapping blocks.
